(19) United States
(12) Patent Application Publication
(10) Pub. No.: US 2024/0313563 A1
(43) Pub. Date: Sep. 19, 2024

(54) ELECTRONIC DEVICE AND CONTROLLING METHOD THEREOF

(71) Applicant: SAMSUNG ELECTRONICS CO., LTD., Suwon-si (KR)

(72) Inventors: Wonjae LEE, Suwon-si (KR); Kwanyoung Kim, Suwon-si (KR); Kihyun Song, Suwon-si (KR); Sukhoon Yoon, Suwon-si (KR); Jongkeun Lee, Suwon-si (KR)

(73) Assignee: SAMSUNG ELECTRONICS CO., LTD., Suwon-si (KR)

(21) Appl. No.: 18/670,311

(22) Filed: May 21, 2024

Related U.S. Application Data
(63) Continuation of application No. PCT/KR2022/017782, filed on Nov. 11, 2022.

(30) Foreign Application Priority Data
Jan. 4, 2022 (KR) 10-2022-0001136

(51) Int. Cl. H02J 7/00; G01R 19/30; G01R 31/371; G01R 31/3835; G01R 31/396

(52) U.S. Cl. CPC H02J 7/0048; G01R 19/30; G01R 31/371; G01R 31/3835; G01R 31/396

(57) ABSTRACT

An electronic device including a battery; a memory configured to store information regarding a changed voltage value of the battery based on a unit time elapsing after charging of the battery is started; and a processor configured to: based on the charging of the battery being started, identify an initial voltage value of the battery; based on the unit time elapsing after the charging of the battery is started, identify the changed voltage value of the battery corresponding to a time at which the unit time elapses based on the information stored in the memory and the initial voltage value; and identify a current charge of the battery based on the changed voltage value.

### CROSS REFERENCE TO RELATED APPLICATION(S)

This application is a continuation of International Application No. PCT/KR2022/017782, filed on Nov. 11, 2022, in the Korean Intellectual Property Receiving Office, which is based on and claims priority to Korean Patent Application No. 10-2022-0001136, filed on Jan. 4, 2022, in the Korean Intellectual Property Office, the disclosures of which are incorporated by reference herein in their entireties.

### BACKGROUND

### 1. Field

The disclosure relates to an electronic device and a controlling method thereof, and more particularly, to an electronic device that identifies a remaining charge of a battery and a controlling method thereof.

### 2. Description of Related Art

In order to check a remaining charge of a battery in an electronic device, there is a method for measuring a remaining charge by applying current to the battery, and a method for measuring a voltage value of the battery.

When applying current to the battery, a separate current measurement IC chip may be used, and power loss may occur when measuring current. Therefore, the method of measuring a voltage value of the battery is mainly used.

However, if the battery is below the threshold capacity for fast charging, the voltage value of the battery may increase rapidly during fast charging, and then decrease rapidly and converge. Therefore, if the voltage value of the battery measured in real time is provided as it is, the user may receive distorted information regarding the remaining battery charge.

### SUMMARY

According to an aspect of the disclosure, an electronic device may include a battery; a memory configured to store information regarding a changed voltage value of the battery based on a unit time elapsing after charging of the battery is started; and a processor configured to: based on the charging of the battery being started, identify an initial voltage value of the battery; based on the unit time elapsing after the charging of the battery is started, identify the changed voltage value of the battery corresponding to a time at which the unit time elapses based on the information stored in the memory and the initial voltage value; and identify a current charge of the battery based on the changed voltage value.

The electronic device may further include a communication interface, where the processor is further configured to, based on the current charge of the battery being identified, transmit information regarding the current charge to an external device through the communication interface.

The electronic device may further include a display, where the processor is further configured to: identify a remaining charge of the battery based on the initial voltage value; control the display to display a user interface (UI) including information regarding the remaining charge; and based on the current charge of the battery being identified, update information included in the UI based on the current charge.

The processor may be further configured to: based on a threshold time elapsing after the charging of the battery is complete, obtain a first voltage value of the battery; and update information included in the UI based on a charge amount corresponding to the first voltage value.

During the charging of the battery, a voltage value of the battery may overshoots, attenuates and converges, where the threshold time is based on a time for the voltage value to converge to the first voltage value after overshooting.

The electronic device may further include a voltage sensing circuit configured to sense a voltage value of the battery; and a counter configured to count whether the unit time has elapsed after starting the charging of the battery, where the processor is further configured to: identify a remaining charge of the battery based on an initial voltage value of the battery sensed by the voltage sensing circuit; and identify whether the unit time has elapsed based on counting information received from the counter.

The information stored in the memory may include information regarding a changed first voltage value of the battery based on a first unit time elapsing after the charging of the battery is started, and a changed second voltage value of the battery based on a second unit time elapsing after the first unit time has elapsed.

The information stored in the memory may include information regarding a first voltage range corresponding to the changed first voltage value and information regarding a second voltage range corresponding to the changed second voltage value, where the processor is further configured to: based on the initial voltage value of the battery falling within the first voltage range, identify a remaining charge of the battery based on the changed first voltage value; and based on the initial voltage value of the battery falling within the second voltage range, identify a remaining charge of the battery based on the changed second voltage value.

The processor may be further configured to: identify the changed first voltage value as either a minimum value or an average value of voltage values that fall within the first voltage range; and identify the changed second voltage value as either a minimum value or an average value of values that fall within the second voltage range.

The battery may be a super-capacity battery.

According to an aspect of the disclosure, a controlling method of an electronic device may include: based on charging of a battery being started, identifying an initial voltage value of the battery; based on a unit time elapsing after the charging of the battery is started, identifying a changed voltage value of the battery corresponding to a time at which the unit time elapses based on the initial voltage value and information regarding the changed voltage value of the battery when the unit time has elapsed; and identifying a current charge of the battery based on the changed voltage value.

The controlling method may further include, based on the current charge of the battery being identified, transmitting information regarding the current charge to an external device through a communication interface.

The controlling method may further include: identifying a remaining charge of the battery based on the initial voltage value; displaying a user interface (UI) including information regarding the identified remaining charge; and based on the current charge of the battery being identified after the charging of the battery is started, updating information included in the UI based on the current charge.

The controlling method may further include: based on a threshold time elapsing after the charging of the battery is completed, obtaining a first voltage value of the battery; and updating information included in the UI based on a charge amount corresponding to the obtained first voltage value.

During the charging of the battery, a voltage value of the battery overshoots, attenuates and converges, where the threshold time is calculated based on a time it takes for the voltage value to converge to the first voltage value after overshooting.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1A is a view provided to explain a method of identifying a remaining charge of a battery according to an embodiment;

FIG. 1B is a view provided to explain a method of identifying a remaining charge of a battery according to an embodiment;

FIG. 2 is a block diagram provided to explain configuration of an electronic device according to an embodiment;

FIG. 3 is a view provided to explain information stored in a memory according to an embodiment;

FIG. 4 is a view provided to explain a method of obtaining second information according to an embodiment;

FIG. 5A and FIG. 5B are views provided to explain a method of displaying a remaining charge of a battery after charging is started according to an embodiment;

FIG. 6 is a view provided to explain a method of displaying a remaining charge of a battery after charging is completed, according to an embodiment;

FIG. 7 is a block diagram provided to explain detailed configuration of an electronic device according to an embodiment;

FIG. 8 is a flowchart provided to explain a method of updating a voltage value of a battery according to an embodiment; and

FIG. 9 is a flowchart provided to explain a controlling method of another electronic device according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

The terms used in this specification will be briefly explained, and the present disclosure will be described in detail.

The terms including technical or scientific terms used in the disclosure may have the same meanings as generally understood by those skilled in the art, but may vary with the emergence of new technologies, etc. In addition, in constant cases, the terms have been chosen arbitrarily by the applicant, in which case their meaning will be described in detail in the applicable description of the disclosure. Accordingly, terms used in this disclosure should be defined based on their meaning and the context of the disclosure as a whole, and not merely on their designation.

In this specification, expressions such as “has,” “may have,” “includes,” or “may comprise” refer to the presence of a feature (e.g., a numerical, functional, behavioral, or component aspect) and do not exclude the presence of additional features.

The expression “at least one of A or B” should be understood to refer to either “A” or “B” or “A and B”.

As used herein, the expressions “first,” “second,” “first,” or “second,” and the like may refer to various components regardless of their sequence and/or importance, and are used only to distinguish one component from another and are not intended to limit such components.

When a component (e.g., a first component) is referred to as being “operatively or communicatively coupled with/to” or “connected to” another component (e.g., a second component), it is to be understood that the component may be directly connected to the other component, or may be connected through another component (e.g., a third component).

It is to be understood that singular forms include plural referents unless the context clearly dictates otherwise. In this application, the terms “comprising” or “consisting of” and the like are intended to designate the presence of the features, numbers, steps, actions, components, parts, or combinations thereof described in the specification, and are not to be understood as precluding the possibility of the presence or addition of one or more other features, numbers, steps, actions, components, parts, or combinations thereof.

In the present disclosure, a “module” or “part” performs at least one function or operation and may be implemented in hardware or software, or a combination of hardware and software. Further, a plurality of “modules” or a plurality of “parts” may be integrated into at least one module and implemented on at least one processor.

Hereinafter, an embodiment of the present disclosure will be described in greater detail with reference to the accompanying drawings.

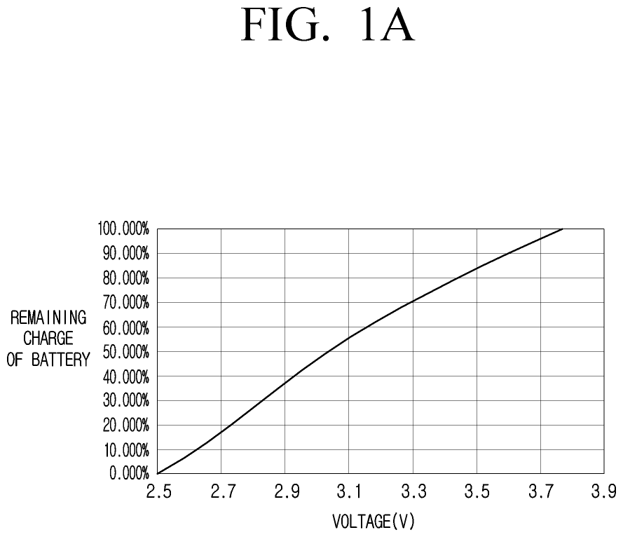

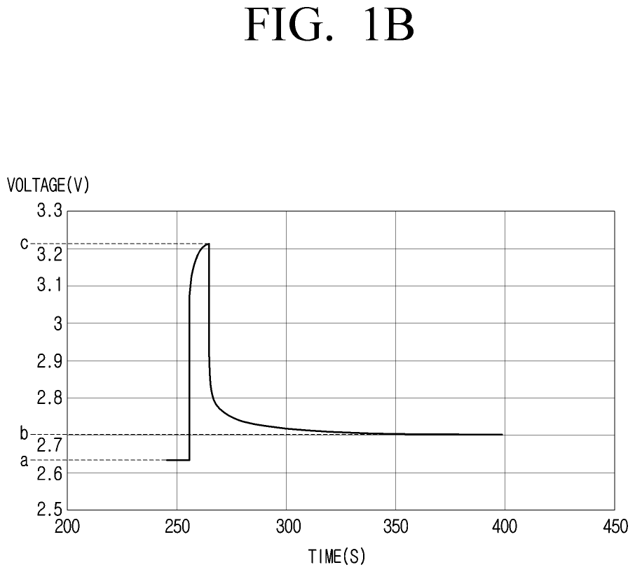

FIGS. 1A and 1B are views provided to explain a method of identifying a remaining charge of a battery according to an embodiment.

According to an embodiment, the electronic device 100 may be a smartphone, tablet PC, smart TV, cell phone, personal digital assistant (PDA), laptop, media player, e-book terminal, digital broadcast terminal, navigation, MP3 player, digital camera, home appliance, and other mobile or non-mobile computing device, but is not limited thereto. In addition, the electronic device 100 may be a wearable terminal, such as a watch, eyeglasses, hair bands and rings, or a remote control device, such as a remote controller. However, the electronic device 100 is not limited thereto, and the electronic device 100 may include any electronic device having a battery.

The electronic device 100 may detect a voltage value of a battery to identify a remaining charge of the battery. Referring to FIG. 1A, the electronic device 100 may store information in the memory regarding a magnitude of a remaining charge of the battery corresponding to a magnitude of the voltage value of the battery, and the electronic device 100 may, when the voltage value of the battery is detected, identify the remaining charge of the battery corresponding to the magnitude of the detected voltage value of the battery through the information stored in the memory.

A battery below threshold capacity capable of fast charging, such as a super-capacity battery, may be charged in a way that the voltage value overshoots and then attenuates and converges as the battery is fast charged. According to FIG. 1B, when an initial voltage value (a) of the battery measured during the continuation of charging is identified, the voltage value of the battery goes through an overshooting value (c) and converges to a first voltage value (b).

In this case, if the user is provided with information regarding the remaining charge of the battery corresponding to the magnitude of the overshooting value (c), the user may be provided with information regarding the distorted remaining charge.

Accordingly, hereinafter, one or more embodiments of predicting and providing information corresponding to the current battery charge based on previously stored data will be described.

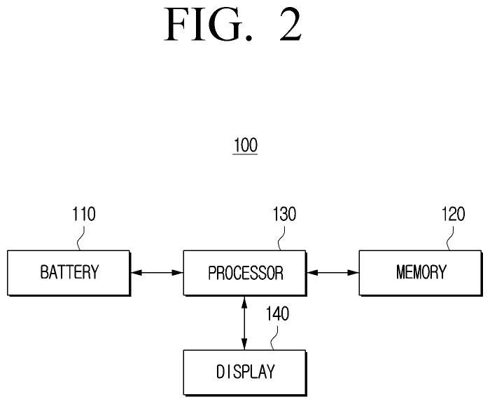

FIG. 2 is a block diagram provided to explain configuration of an electronic device according to an embodiment.

Referring to FIG. 2, the electronic device 100 may include a battery 110, a memory 120, and a processor 130.

The battery 110 may provide power to at least one component of the electronic device 100. According to an embodiment, the battery 110 may include, for example, a rechargeable secondary cell or fuel cell.

According to an embodiment, the battery 110 may be a battery below threshold capacity that is capable of fast charging. For example, the battery 110 may be a super-capacity battery (e.g., a super cap battery). A super cap battery, also known as an ultra capacitor (UC) or electric double layer capacitor (EDLC), may have a power density (instantaneous output, max current) that is greater than that of a lithium-ion battery, and may be capable of fast charging when a constant amount of current is supplied (typically, 10 amps or more). However, the battery 110 of the present disclosure is not limited to a super-capacity battery, and may include any battery below threshold capacity that is capable of fast charging.

The memory 120 according to an embodiment may store information for various embodiments. The memory 120 may be implemented in a memory form embedded in the electronic device 100 or in a memory form capable of performing communication with (or detachable from) the electronic device 100 according to the data storage purpose. For example, data for driving the electronic device 100 may be stored in the memory embedded in the electronic device 100, and data for the expansion function of the electronic device 100 may be stored in the memory detachable from the electronic device 100. The memory embedded in the electronic device 100 may be implemented as at least one of a volatile memory (e.g. a dynamic RAM (DRAM), a static RAM (SRAM), or a synchronous dynamic RAM (SDRAM)) and a non-volatile memory (e.g., a one time programmable ROM (OTPROM), a programmable ROM (PROM), an erasable and programmable ROM (EPROM), an electrically erasable and programmable ROM (EEPROM), a mask ROM, a flash ROM, a flash memory (e.g. a NAND flash or a NOR flash), a hard drive, or a solid state drive (SSD)). In addition, the memory capable of performing communication with the electronic device 100 may be implemented in the form of a memory card (e.g., a compact flash (CF), a secure digital (SD), a micro secure digital (Micro-SD), a mini secure digital (Mini-SD), an extreme digital (xD), or a multi-media card (MMC)), an external memory connectable to a USB port (e.g., a USB memory), or the like.

According to an embodiment, the memory 120 may be implemented as a single memory that stores data generated by the various operations according to the present disclosure. However, according to other embodiments, the memory 120 may store each of different types of data, or may be implemented to include a plurality of memories that each store data generated at different stages.

According to an embodiment, the memory 120 may store information (hereinafter, referred to as first information) regarding a remaining charge corresponding to a voltage value of the battery 110 as shown in FIG. 1A.

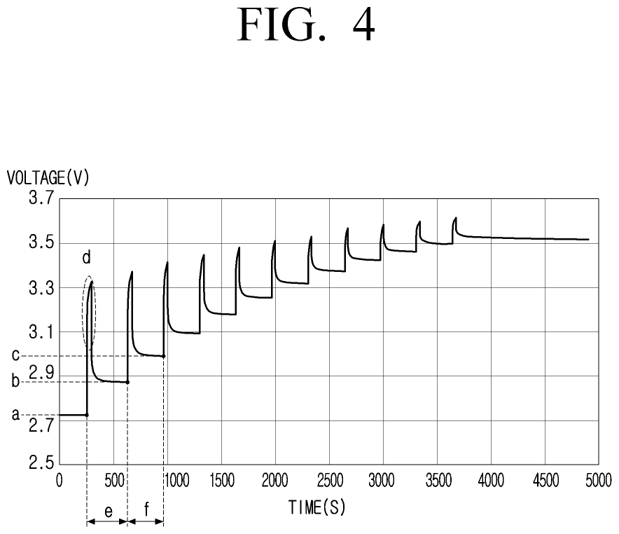

In addition, the memory 120 may store information (hereinafter, referred to as second information) regarding a changed voltage value of the battery 110 as a unit time has elapsed after charging of the battery is started. This information may be obtained through experiments, formulas, programs, or the like, and a method of obtaining such information will be described in greater detail with reference to FIG. 4.

The processor 130 is operatively coupled to the battery 110 and the memory 120 to control the overall operation of the electronic device 100. The processor 130 may execute at least one instruction stored in the memory 120 to perform operations of the electronic device 100 in accordance with various embodiments of the present disclosure.

According to an embodiment, the processor 130 may be implemented as a digital signal processor (DSP), a microprocessor, a Graphics Processing Unit (GPU), an Artificial Intelligence (AI) processor, a Neural Processing Unit (NPU), or a Time controller (TCON). However, the processor 130 is not limited thereto, and the processor one or more of a central processing unit (CPU), a Micro Controller Unit (MCU), a micro processing unit (MPU), a controller, an application processor (AP), a communication processor (CP), an advanced RISC machine (ARM) processor, or may be defined by the corresponding term. In addition, the processor 130 may be implemented in a system-on-chip (SoC) or a large scale integration (LSI) in which a processing algorithm is embedded, or may be implemented in the form of an application specific integrated circuit (ASIC) or a field programmable gate array (FPGA).

According to an embodiment, when charging of the battery 110 is started, the processor 130 may identify a remaining charge of the battery based on an initial voltage value of the battery 110. Here, the initial voltage value of the battery 110 refers to a voltage magnitude of the battery 110 corresponding to a time when charging of the battery 110 is started. According to an embodiment, the processor 130 may obtain (or, detect) an initial voltage value of the battery 110 through a voltage sensing circuit, and identify the remaining charge of the battery 110 corresponding to the obtained voltage value based on the first information stored in the memory 120.

According to an embodiment, the processor 130 may obtain an initial voltage value of the battery 110, and identify a remaining charge of the battery corresponding to the initial voltage value of the battery 110 based on the first information regarding the remaining charge of the battery corresponding to the changed voltage value stored in the memory 120. For example, the processor 130 may obtain an initial voltage value of the battery 110 as 3.3 (V), and obtain the remaining charge of the battery 110 as 70% based on the first information stored in the memory 120. As a result, the processor 130 may identify the remaining charge of the battery 110 corresponding to the obtained initial voltage value.

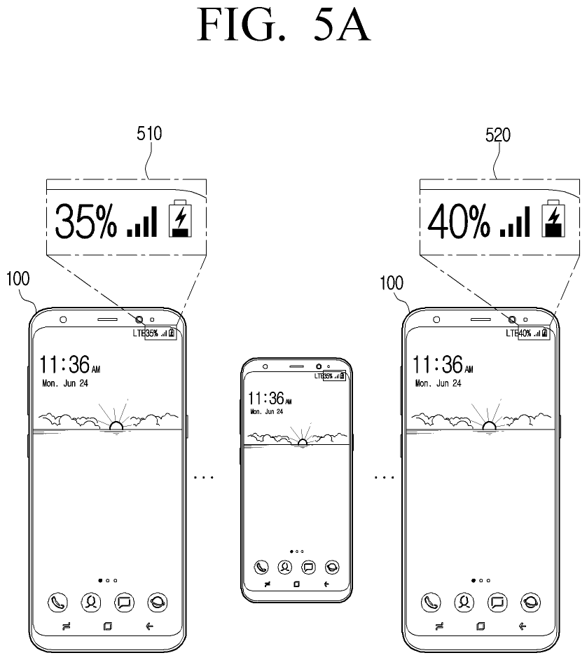

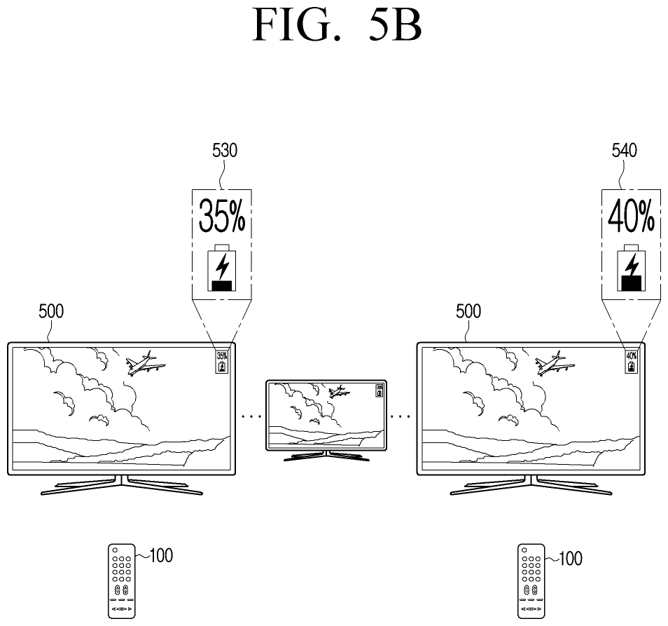

Subsequently, the processor 130 may transmit information regarding the identified remaining charge to an external device, or provide the same through a display, which will be described in greater detail with reference to FIGS. 5A and 5B.

Subsequently, according to an embodiment, when a unit time has elapsed after the battery charging is started, the processor 130 may identify, based on the second information stored in the memory 120, a changed voltage value of the battery 110 corresponding to the time when the unit time has elapsed. Here, the changed voltage value of the battery 110 refers to a voltage value that has changed as the battery 110 is charged based on the pre-obtained initial voltage value of the battery 110.

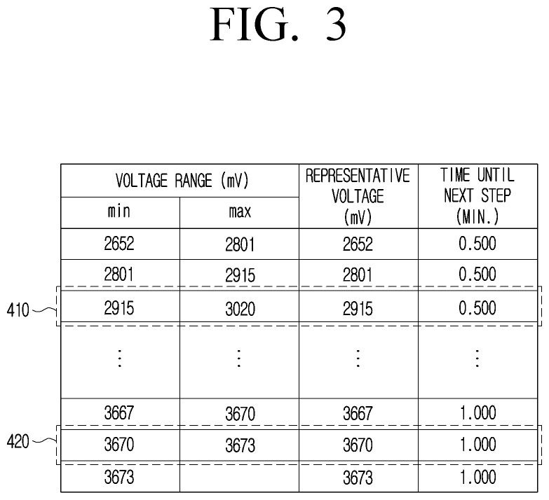

According to an embodiment, the processor 130 may identify whether a unit time has elapsed based on counting information received from a counter, and identify a changed voltage value of the battery 110 corresponding to the time when the unit time has elapsed based on the second information stored in the memory 120. Here, the counting information may be a pulse signal having a signal period corresponding to a magnitude of the unit time. The second information stored in the memory 120 may include information regarding a voltage value corresponding to a charging time of the battery 110, which will be described in greater detail with reference to FIG. 3.

FIG. 3 is a view provided to explain information stored in a memory according to an embodiment.

According to an embodiment, the second information stored in the memory 120 may include information regarding a changed first voltage value of the battery 110 as a unit time has elapsed after charging of the battery 110 is started, and information regarding a changed second voltage value of the battery 110 as a further unit time has elapsed. The unit time (or, time to the next step) may be 0.5 minutes or 1 minute as shown in FIG. 3, but is not limited thereto. The unit time may vary depending on model information of the battery 110 or type of charging terminal.

According to an embodiment, the second information may include a representative voltage and unit time information per voltage range, as shown in FIG. 3. For example, the voltage range may include a minimum voltage value and a maximum voltage value, and the representative voltage may be set to the minimum voltage value of the corresponding voltage range, but is not limited thereto. Further, the unit time for each voltage range may be set to a constant time regardless of the voltage range, but may vary depending on the voltage range.

FIG. 4 is a view provided to explain a method of obtaining second information according to an embodiment.

Hereinafter, it is described that the processor 130 obtains the second information for convenience of explanation, but the second information may be information that has already been obtained and stored during the manufacture of the electronic device 100.

As shown in FIG. 4, when charging of a super-capacity battery is started, the voltage value of the battery 110 may overshoot (d) from the initial voltage value (a) and then attenuate to converge to a first voltage value (b) that is greater than the initial voltage value (a) after a threshold time has elapsed. The processor 130 may store in the memory 120 the first voltage value (b) of the battery 110 as the threshold time (e) has elapsed after charging of the battery 110 is started, from the initial voltage (a).

Subsequently, the processor 130 may store in the memory 120 the second voltage value (c) of the battery 110 as a further threshold time (f) has elapsed from the first voltage value (b). The threshold time is the time to attenuate and converge after the overshooting (d), which may be a constant value, but may vary within a threshold error.

In addition, the processor 130 may obtain and store the information regarding the change in the voltage value as the threshold time has elapsed while the initial voltage value is greater than (a) in the same manner as described above. When this process is repeated, the second information as shown in FIG. 3 may be obtained. The information regarding change in the voltage value may be obtained by utilizing a voltage sensing circuit and a counter or the like.

Referring back to FIG. 2, according to an embodiment, the processor 130 may identify a voltage range within which the initial voltage value of the battery 110 falls, and identify a remaining charge of the battery 110 based on the identified initial voltage value.

For example, if the initial voltage value of the battery 110 falls within a first voltage range, the processor 130 may identify a remaining charge of the battery 110 based on the changed first voltage value, which is a representative voltage corresponding to the first voltage range, and if the initial voltage value of the battery 110 falls within a second voltage range, the processor 130 may identify a remaining charge of the battery 110 based on the changed second voltage value, which is a representative voltage corresponding to the second voltage range. In this case, according to an embodiment, the processor 130 may identify one of a minimum value or an average value of the voltage values in the first voltage range as the changed first voltage value, and one of a minimum value or an average value of the voltage values in the second voltage range as the changed second voltage value. For example, the processor 130 may identify the representative voltage value (or, the changed first voltage value) as a minimum value from among the voltage values in the first voltage range, but is not limited thereto, and may identify the average value from among the voltage values in the first voltage range as the changed first voltage value. In an embodiment, the processor 130 may identify a maximum value from among the voltage values in the first voltage range as the changed first voltage value.

For example, if an initial voltage value of the battery 110 is identified as 3000 mV, the processor 130 may identify the initial voltage value of the battery 110 as falling within a first voltage range (2915 mV to 3020 mV, 410), and may identify a remaining charge of the battery 110 based on a representative voltage value of 2915 mV corresponding to the first voltage range. In this case, the processor 130 may identify the remaining charge of the battery 110 through information (FIG. 1A) regarding a remaining charge corresponding to a changed voltage value of the battery 110 stored in the memory 120.

According to an embodiment, when a voltage value of the battery 110 is identified, the processor 130 may identify, based on the second information stored in the memory 120, a changed voltage value of the battery 110 as a unit time has elapsed after charging of the battery 110 is started, and identify a current charge of the battery 110 based on the identified changed voltage value. For example, it is assumed that an initial voltage value is identified as 2900 mV and a voltage value is identified as 2801 mV. When the processor 130 identifies that a unit time, 0.5 minutes, has elapsed after charging of the battery 110 is started, the processor 130 may identify the changed voltage value of the battery 110 as 2915 mV, which is a representative voltage value for the next step 410, and update the remaining charge of the battery 110 based on the identified changed voltage value.

According to another embodiment, it is assumed that the voltage value is identified as 3667 mV in response to the initial voltage value being identified as 3668 mV. When the processor 130 identifies that a unit time, one minute, has elapsed after charging of the battery 110 is started, the processor 130 may identify the changed voltage value of the battery 110 as 3670 mV, which is a representative voltage value for the next step 420, and update the remaining charge of the battery 110 based on the identified changed voltage value.

Accordingly, the processor 130 may identify the remaining charge of the battery 110 over time without identifying a voltage value of the battery 110 after charging of the battery 110 is started.

The processor 130 may identify a current charge of the battery 110 based on the identified changed voltage value, and update the information included in the user interface (UI) based on the identified current charge.

For example, the remaining charge of the battery 100 may be identified as 28% in response to the initial voltage value being identified as 2.8 V. If one minute has elapsed after charging of the battery 110 is started and the changed voltage value is identified as 2915 mV, the processor 130 may identify the current charge as 40%, which is the amount of charge corresponding to the identified changed voltage value of 2915 mV, based on the information stored in the memory 120, and update the information included in the UI to provide the same to the user.

Subsequently, according to an embodiment, when a threshold time has elapsed after charging of the battery 110 is completed, the processor 130 may obtain a first voltage value of the battery 110 and update the information included in the UI based on the amount of charge corresponding to the obtained first voltage value.

The threshold time may be calculated based on the time it takes for the voltage value to attenuate and converge the first voltage value after overshooting. In this case, the threshold time may be, but is not limited to, 5 minutes, and the value may vary depending on the type of electronic device and the type of battery charging terminal connected to the electronic device. Accordingly, by measuring the voltage value of the battery 110 after the threshold time, errors that may occur due to overshooting of the voltage value after the end of charging can be eliminated and an accurate battery charge can be provided to the user.

According to an embodiment, when a threshold time has elapsed after charging of the battery 110 is completed, the processor 130 may obtain a voltage value of the battery 110 and update the information included in the UI based on the amount of charge corresponding to the obtained voltage value. In this case, from the time when the charging is completed to the time when the information included in the UI is updated as the threshold time has elapsed, the processor 130 may not update the information included in the UI and continue to display information corresponding to the existing amount of charge.

The amount of charge at the time when the charging is completed may be identified as 100%. If it is identified that a threshold time of 5 minutes has elapsed after charging of the battery 110 is completed, the processor 130 may obtain a voltage value of the battery 110 through the voltage sensing circuit. If the obtained voltage value is identified as 3670 mV, the processor 130 may identify the amount of charge corresponding to the voltage value as 95% based on the information stored in the memory 120, and update the information included in the UI based thereon. In this case, the processor 130 may display a UI corresponding to the 95%, which is the amount of charge after the charging is completed, from the time when the charging is completed to the time when the information included in the UI is updated.

FIGS. 5A and 5B are views provided to explain a method of displaying a remaining charge of a battery after charging is started according to an embodiment.

According to an embodiment, the processor 130 may control the display to show a UI that includes information regarding the remaining charge identified based on the initial voltage value, and update the information included in the UI based on the identified current charge after charging is started.

According to another embodiment, the processor 130 may transmit the information included in the UI to an external device based on information regarding the remaining charge identified based on the initial voltage value and the current charge identified after charging is started.

Referring to FIG. 5A, according to an embodiment, when charging of the battery 110 is started, the processor 130 may identify an initial voltage value of the battery 110 as 2.9 V, identify a remaining charge of the battery 110 as 35% based on information stored in the memory 120, and control the display 140 to display a corresponding UI 510.

Subsequently, when it is identified that a unit time has elapsed, the processor 130 may identify the changed voltage value of the battery 110 as 2.915 V corresponding to the elapse of the unit time, 0.5 minutes, based on the information regarding the changed voltage value of the battery 110 over the elapse of the unit time stored in the memory 120, and identify the corresponding current charge as 40%. As the current charge is identified as 40%, the processor 130 may control the display 140 to display a corresponding UI 520.

From the time when the UI corresponding to information regarding the remaining charge of the battery 110 is displayed to the time when the UI corresponding to information regarding the charge of the battery 110 is updated, the UI corresponding to information regarding the remaining charge of the battery 110 may be displayed based on the UI corresponding to the existing remaining charge.

According to an embodiment, the processor 130 may transmit information regarding the remaining charge of the electronic device 100 to an external device through a communication interface to enable the external device to display a UI regarding the remaining charge of the electronic device 100. According to an embodiment, the electronic device 100 may be a remote control device, such as a remote controller that does not have a display.

Referring to FIG. 5B, the processor 130 may transmit information regarding the remaining charge level identified based on the initial voltage value and/or information regarding the identified current charge level after charging is started, to an external device 500, such as a TV, through a communication interface. In this case, the external device 500 (e.g., a processor of the external device 500) may display, through a display, a UI 530 that includes information regarding the remaining charge identified based on the initial voltage value received from the electronic device 100 and a UI 540 that includes information regarding the identified current charge after charging is started.

However, according to an embodiment, the processor 130 may transmit information regarding an initial voltage value, a changed voltage value, and/or a voltage value of the battery 110 to the external device 500 through the communication interface, rather than information regarding the remaining charge of the battery 110. In this case, the external device 500 may identify the remaining charge and the current charge of the battery 110 based on the information regarding the received voltage values and display the in a UI. In this case, the external device 500 may store information for calculating the remaining charge as shown in FIGS. 3 and 4. In this case, the processor 130 may transmit counting information as well as information regarding the voltage value to the external device 500, and the external device 500 may control the display to identify the remaining charge of the electronic device 100 corresponding to a point in time when a unit time has elapsed and update the information regarding the UI based on the counting information received from the electronic device 100.

The processor 130 may transmit information regarding the remaining charge to the external device 500 when a predetermined condition is satisfied. The predetermined condition may include at least one of: when it is identified that charging of the battery 110 is started, when a unit time has elapsed after charging of the battery 110 is started, when it is identified that charging is completed, and when a user input is detected through the user interface. However, even in this case, the voltage value itself, rather than information regarding the remaining charge, may be transmitted to an external device, e.g., a TV. According to an embodiment, when it is identified that a unit time has elapsed after charging of the battery 110 is started, the processor may transmit information regarding the current charge (or a battery voltage value) corresponding to the elapsed unit time to the TV through the communication interface, and the TV may control the display to show a UI that includes the received information regarding the remaining charge (or information regarding the remaining charge obtained based on the received battery voltage value).

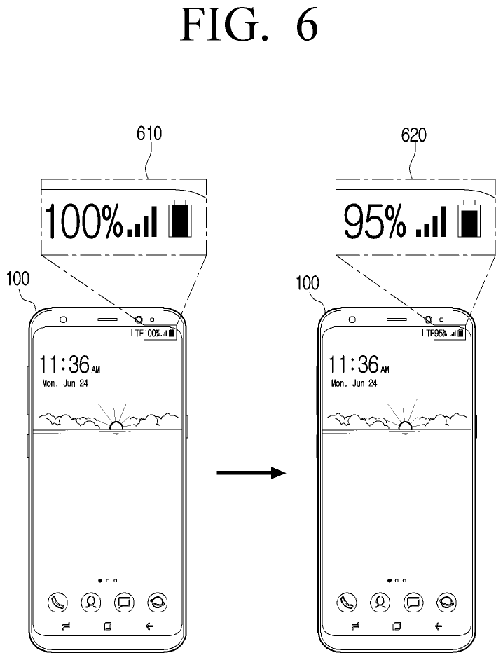

FIG. 6 is a view provided to explain a method of displaying a remaining charge of a battery after charging is completed, according to an embodiment.

According to an embodiment, the user may be finished charging after the current charge of the battery 110 is identified as 100%. As the current charge of the battery 110 is identified as 100%, the processor may update and display a corresponding UI 610. Subsequently, the processor 130 may identify whether a threshold time of 5 minutes has elapsed after charging of the battery 110 is completed through the counting information received through the counter. When it is identified that 5 minutes has elapsed, the processor 130 may obtain a voltage value of the battery 110 of 3725 mV through the voltage sensing circuit. The processor 130 may identify the amount of charge corresponding to the voltage value as 95% through the information stored in the memory 120, and control the display 140 to display a corresponding UI 620.

The user may not receive distorted information due to the overshooting of the voltage value that occurs when charging the battery, and may get accurate information regarding the amount of battery charge.

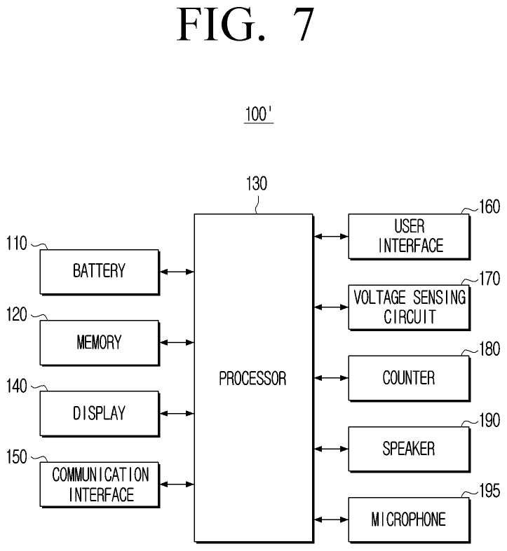

FIG. 7 is a block diagram provided to explain detailed configuration of an electronic device according to an embodiment.

Referring to FIG. 7, an electronic device 100′ may include a battery 110, a memory 120, a processor 130, a display 140, a communication interface 150, a user interface (UI) 160, a voltage sensing circuit 170, a counter 180, a speaker 190, and a microphone 195. Any configuration shown in FIG. 7 that is redundant of the configuration shown in FIG. 2 will be omitted from further description.

The display 140 may be implemented as a display including a self-light emitting element or a display including a non self-light emitting element and a backlight. For example, the display 140 may be implemented in various types of displays such as a liquid crystal display (LCD), an organic light emitting diode (OLED) display, a light emitting diode (LED) display, a micro light emitting diode (micro LED) display, a mini LED display, a plasma display panel (PDP), a quantum dot (QD) display, a quantum dot light-emitting diode (QLED) display. The display 140 may also include a drive circuit, a backlight unit, and the like, which may be implemented in the form of an a-si TFT, a low temperature poly silicon (LTPS) TFT, an organic TFT (OTFT), and the like.

The display 140 may be implemented as a touch screen combined with a touch sensor, a flexible display, a rollable display, a three-dimensional (3D) display, a display in which a plurality of display modules are physically connected, etc. In addition, the display 140 may include a touch screen so that a program can be executed using a finger or a pen (e.g., a stylus pen).

The communication interface 150 may perform communication with a network device including other user terminals, and the like. According to an embodiment, the communication interface 150 may include a wireless communication module such as a Wi-Fi module, a Bluetooth module, and the like. However, the communication interface 150 is not limited thereto, and may perform communication based on various wireless communication standards such as Zigbee, third generation (3G), third generation partnership project (3GPP), long term evolution (LTE), LTE advanced (LTE-A), fourth generation (4G), fifth generation (5G), and the like, a infrared Data Association (IrDA) technology, and the like.

The user interface 160 is a configuration for the electronic device 100′ to perform interaction with a user. For example, the user interface 160 may include, but is not limited to, at least one of a touch sensor, a motion sensor, a button, a jog dial, a switch, a microphone, or a speaker.

The voltage sensing circuit 170 may be a circuit for measuring the internal voltage of the battery 110, and may include a partial pressure resistor used for measuring the voltage at both ends of the battery 110, a comparator for comparing the voltage value at both ends of the battery 110 measured through the partial pressure resistor with a stored reference voltage value, a delay circuit for delaying driving for a random amount of time based on a signal output from the comparator, and a protection circuit.

The counter 180 is a device capable of generating a pulse signal with a preset interval of unit time and transmitting the same to the processor 130. The processor 130 may receive the counting information (or, pulse signals) generated by the counter 180 to identify the amount of charge of the battery 110 after the unit time has elapsed.

The speaker 190 may include a tweeter for reproducing high-pitched sound, a midrange for reproducing mid-range sound, a woofer for reproducing low-pitched sound, a subwoofer for reproducing extremely low-pitched sound, an enclosure for controlling resonance, and a crossover network for dividing the frequency of the electrical signal input to the speaker into bands.

The speaker 190 may output an acoustic signal to the outside of the electronic device 100′. The speaker 190 may output multimedia playback, recording playback, various notification sounds, voice messages, etc. The electronic device 100′ may include an audio output device such as the speaker 190, but may also include an output device such as an audio output terminal. The speaker 190 may provide obtained information, information processed or produced based on the obtained information, response results to a user's voice, or operation results in the form of a voice.

Microphone 195 may refer to a module that obtains sound and converts it into an electrical signal, and may be condenser microphone, ribbon microphone, moving coil microphone, piezoelectric element microphone, carbon microphone, or micro electro mechanical system (MEMS) microphone. It may also be implemented in a nondirectional, bidirectional, unidirectional, sub-cardioid, super-cardioid, or hyper-cardioid manner.

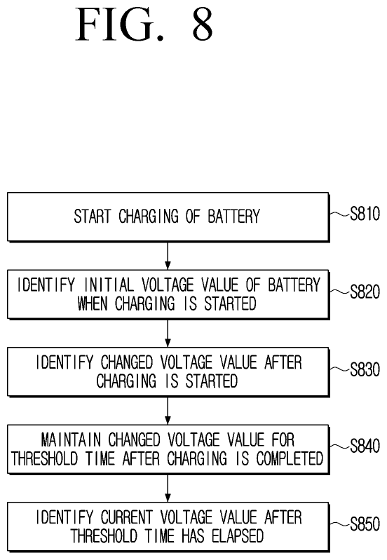

FIG. 8 is a flowchart provided to explain a method of updating a voltage value of a battery according to an embodiment.

Referring to FIG. 8, charging of the battery 110 may be first initiated (S810). In this case, the battery may be a super-capacity battery, and may be fast-charged, in which a of a constant magnitude or greater is supplied per unit time.

Subsequently, the processor 130 may identify an initial voltage value of the battery 110 corresponding to a point in time when charging of the battery 110 is started (S820). The processor 130 may identify a remaining charge of the battery 110 based on the initial voltage value of the battery,

Subsequently, when charging is started, the processor 130 may identify a changed voltage value after charging is started (S830). In this case, the processor 130 may update the changed voltage value of the battery 110 every time a unit time of 0.5 minutes has elapsed based on the information stored in the memory 120. The changed voltage value of the battery 110 may be determined based on the initial voltage value of the battery, and the changed voltage value corresponding to a time when the unit time has elapsed based on the initial voltage value may be obtained through the information stored in the memory 120.

Subsequently, when the charging is completed, the processor 130 may maintain the changed voltage value for a threshold time after the charge is completed (S840). In this case, when the battery voltage value at the point in time when the charging is identified as being completed is identified, the voltage value of the battery 110 may be maintained at the changed voltage value until the threshold time has elapsed and a new voltage value is identified.

Subsequently, when it is identified that the threshold time has elapsed, the processor 130 may identify the voltage value. In this case, the threshold time may be 5 minutes, and the processor 130 may identify whether the threshold time has elapsed based on counting information obtained through the counter. The voltage value may be identified through the voltage sensing circuit rather than information stored in the memory 120, and when the identified voltage value differs from the battery voltage value at the point in time when charging is identified as being completed, the voltage value of the battery 110 may be updated with the voltage value.

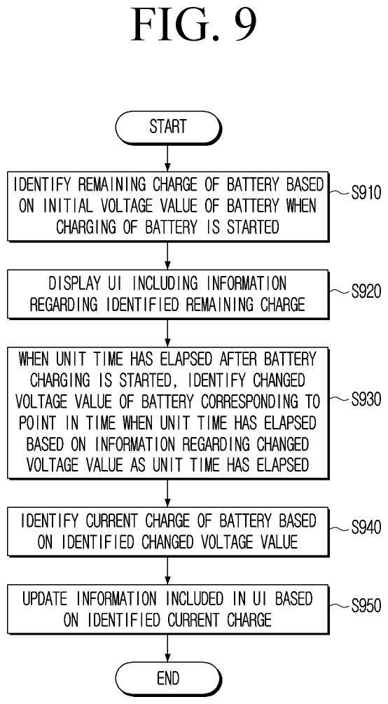

FIG. 9 is a flowchart provided to explain a controlling method of another electronic device according to an embodiment.

According to the controlling method of the electronic device illustrated in FIG. 9, when charging of the battery is started, a remaining charge of the battery may be identified (S910) based on an initial voltage value of the battery. Step S910 may include identifying the remaining charge of the battery based on the initial voltage value of the battery received from the voltage sensing circuit. In addition, the battery may be a super-capacity battery.

Subsequently, a UI including information regarding the identified remaining charge is displayed (S920).

Then, when a unit time has elapsed after the battery charging is started, a changed voltage value of the battery corresponding to the point in time when the unit time has elapsed may be identified based on the information regarding the changed voltage value of the battery as the unit time has elapsed (S930).

Step S930 may include identifying whether a unit time has elapsed based on the counting information received from the counter. The information regarding the changed voltage value of the battery may include information regarding a changed first voltage value of the battery as the unit time (e.g., first unit time) has elapsed after the charging of the battery is started, and information regarding a changed second voltage value of the battery as a further unit time (e.g., second unit time) has elapsed.

In addition, the information regarding the changed voltage value of the battery may include information regarding a first voltage range corresponding to the first voltage value and a second voltage range corresponding to the second voltage value, and the step of identifying the remaining charge of the battery may include identifying the remaining charge of the battery based on the changed first voltage value when the initial voltage value of the battery is in the first voltage range, and identifying the remaining charge of the battery based on the changed second voltage value when the initial voltage value of the battery is in the second voltage range.

The step of identifying the remaining charge of the battery may further include identifying at least one of a minimum value or an average value of the voltage values in the first voltage range as the changed first voltage value and identifying at least one of a minimum value or an average value of the voltage values in the changed second voltage range as the second voltage value.

Subsequently, the current charge of the battery may be identified based on the identified changed voltage value (S940).

Next, the information included in the UI may be updated based on the identified current charge (S950).

The controlling method may further include obtaining a voltage value of the battery after a threshold time has elapsed after charging of the battery is completed and updating information included in the UI based on a charge amount corresponding to the obtained voltage value. The battery may be charged in a way that the voltage value overshoots and then attenuates and converges a first voltage value as a result of the fast charging, and the threshold time may be calculated based on the time it takes for the voltage value to converge the first voltage value after overshooting.

The controlling method may further include, when the current charge of charge of the battery is identified, transmitting information regarding the identified current charge to an external device through the communication interface.

According to one or more embodiments described above, information corresponding to the current battery charge may be predicted based on prestored data and provided to the user. Accordingly, user satisfaction may be improved as by avoiding sudden change in the remaining charge of the battery.

Meanwhile, methods according to the above-described various embodiments may be implemented in the form of an application that can be installed in the existing electronic device. In addition, the methods according to the above-described various embodiments may be implemented by software upgrades to existing electronic apparatuses, or by hardware upgrades alone. Further, the methods according to the above-described various embodiments may be performed through an embedded server in the electronic device, or through an external server in the electronic device.

Meanwhile, according to an embodiment, the above-described various embodiments may be implemented as software including instructions stored on machine-readable storage media, such as a machine (e.g., a computer). The machine may include a display device (e.g., display device A) according to the disclosed embodiments, as a device capable of calling instructions stored on the storage media and acting upon the called instructions. When the instructions are executed by a processor, the processor may perform the function corresponding to the instructions directly or by utilizing other components under the control of the processor. The instructions may include code generated or executed by a compiler or interpreter. The machine-readable storage medium may be provided in the form of a non-transitory storage medium. Here, “non-transitory storage medium” means only that it is a tangible device and does not distinguish between cases where data is stored on the storage medium on a semi-permanent basis and cases where it is stored on a temporary basis

According to an embodiment, the methods according to the various embodiments described above may be included and provided in a computer program product. The computer program product may be traded as a product between a seller and a purchaser. The computer program product may be distributed in the form of a storage medium that is readable by machines (e.g.: a compact disc read only memory (CD-ROM)), or distributed directly on-line through an application store (e.g.: Play Store™). In the case of on-line distribution, at least a portion of a computer program product may be stored in a storage medium such as the server of the manufacturer, the server of the application store, or the memory of the relay server at least temporarily, or may be generated temporarily.

In addition, each of the components (e.g., modules or programs) according to the various embodiments may include a single entity or a plurality of entities, and some of the corresponding sub-components described above may be omitted or other sub-components may be further included in the various embodiments. Alternatively or additionally, some of the components (e.g., the modules or the programs) may be integrated into one entity, and may perform functions performed by the respective corresponding components before being integrated in the same or similar manner. Operations performed by the modules, the programs or other components according to the various embodiments may be executed in a sequential manner, a parallel manner, an iterative manner or a heuristic manner, and at least some of the operations may be performed in a different order or be omitted, or other operations may be added.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. An electronic device comprising:
a battery;
a memory configured to store information regarding a changed voltage value of the battery based on a unit time elapsing after charging of the battery is started; and
a processor configured to:
based on the charging of the battery being started, identify an initial voltage value of the battery;
based on the unit time elapsing after the charging of the battery is started, identify the changed voltage value of the battery corresponding to a time at which the unit time elapses based on the information stored in the memory and the initial voltage value; and
identify a current charge of the battery based on the changed voltage value.

2. The electronic device as claimed in claim 1, further comprising:
a communication interface,
wherein the processor is further configured to, based on the current charge of the battery being identified, transmit information regarding the current charge to an external device through the communication interface.

3. The electronic device as claimed in claim 1, further comprising:
a display,
wherein the processor is further configured to:
identify a remaining charge of the battery based on the initial voltage value;
control the display to display a user interface (UI) including information regarding the remaining charge; and
based on the current charge of the battery being identified, update information included in the UI based on the current charge.

4. The electronic device as claimed in claim 3, wherein the processor is further configured to:
based on a threshold time elapsing after the charging of the battery is complete, obtain a first voltage value of the battery; and
update information included in the UI based on a charge amount corresponding to the first voltage value.

5. The electronic device as claimed in claim 4, wherein, during the charging of the battery, a voltage value of the battery overshoots, attenuates and converges, and
wherein the threshold time is based on a time for the voltage value to converge to the first voltage value after overshooting.

6. The electronic device as claimed in claim 1, further comprising:
a voltage sensing circuit configured to sense a voltage value of the battery; and
a counter configured to count whether the unit time has elapsed after starting the charging of the battery,
wherein the processor is further configured to:
identify a remaining charge of the battery based on an initial voltage value of the battery sensed by the voltage sensing circuit; and
identify whether the unit time has elapsed based on counting information received from the counter.

7. The electronic device as claimed in claim 1, wherein the information stored in the memory comprises information regarding a changed first voltage value of the battery based on a first unit time elapsing after the charging of the battery is started, and a changed second voltage value of the battery based on a second unit time elapsing after the first unit time has elapsed.

8. The electronic device as claimed in claim 7, wherein the information stored in the memory comprises information regarding a first voltage range corresponding to the changed first voltage value and information regarding a second voltage range corresponding to the changed second voltage value, and
wherein the processor is further configured to:
based on the initial voltage value of the battery falling within the first voltage range, identify a remaining charge of the battery based on the changed first voltage value; and
based on the initial voltage value of the battery falling within the second voltage range, identify a remaining charge of the battery based on the changed second voltage value.

9. The electronic device as claimed in claim 8, wherein the processor is further configured to:
identify the changed first voltage value as either a minimum value or an average value of voltage values that fall within the first voltage range; and
identify the changed second voltage value as either a minimum value or an average value of values that fall within the second voltage range.

10. The electronic device as claimed in claim 1, wherein the battery is a super-capacity battery.

11. A controlling method of an electronic device, the controlling method comprising:
based on charging of a battery being started, identifying an initial voltage value of the battery;
based on a unit time elapsing after the charging of the battery is started, identifying a changed voltage value of the battery corresponding to a time at which the unit time elapses based on the initial voltage value and information regarding the changed voltage value of the battery when the unit time has elapsed; and
identifying a current charge of the battery based on the changed voltage value.

12. The controlling method as claimed in claim 11, further comprising:
based on the current charge of the battery being identified, transmitting information regarding the current charge to an external device through a communication interface.

13. The controlling method as claimed in claim 11, further comprising:
identifying a remaining charge of the battery based on the initial voltage value;
displaying a user interface (UI) including information regarding the identified remaining charge; and
based on the current charge of the battery being identified after the charging of the battery is started, updating information included in the UI based on the current charge.

14. The controlling method as claimed in claim 13, further comprising:
based on a threshold time elapsing after the charging of the battery is completed, obtaining a first voltage value of the battery; and
updating information included in the UI based on a charge amount corresponding to the obtained first voltage value.

15. The controlling method as claimed in claim 14, wherein, during the charging of the battery, a voltage value of the battery overshoots, attenuates and converges; and
wherein the threshold time is calculated based on a time it takes for the voltage value to converge to the first voltage value after overshooting.

16. The controlling method as claimed in claim 11, wherein the identifying the current charge of the battery comprises:
identifying a remaining charge of the battery based on an initial voltage value of the battery sensed by the voltage sensing circuit; and
identifying whether the unit time has elapsed based on counting information received from the counter.

17. The controlling method as claimed in claim 11,
wherein the information stored in the memory comprises information regarding a changed first voltage value of the battery based on a first unit time elapsing after the charging of the battery is started, and a changed second voltage value of the battery based on a second unit time elapsing after the first unit time has elapsed.

18. The controlling method as claimed in claim 17,
wherein the information stored in the memory comprises information regarding a first voltage range corresponding to the changed first voltage value and information regarding a second voltage range corresponding to the changed second voltage value, and
wherein the identifying the remaining charge of the battery further comprises:
based on the initial voltage value of the battery falling within the first voltage range, identifying a remaining charge of the battery based on the changed first voltage value; and
based on the initial voltage value of the battery falling within the second voltage range, identifying a remaining charge of the battery based on the changed second voltage value.

19. The controlling method as claimed in claim 18, wherein the identifying the remaining charge of the battery further comprises:
identifying the changed first voltage value as either a minimum value or an average value of voltage values that fall within the first voltage range; and
identifying the changed second voltage value as either a minimum value or an average value of voltage values that fall within the second voltage range.

20. A non-transitory computer readable recording medium including a program executing a controlling method of an electronic device, the method comprising:
based on charging of a battery being started, identifying an initial voltage value of the battery;
based on a unit time elapsing after the charging of the battery is started, identifying a changed voltage value of the battery corresponding to a time at which the unit time elapses based on the initial voltage value and information regarding the changed voltage value of the battery when the unit time has elapsed; and
identifying a current charge of the battery based on the changed voltage value.
